(19) United States
(12) Patent Application Publication
(10) Pub. No.: US 2003/0015756 A1
(43) Pub. Date: Jan. 23, 2003

(54) Semiconductor structure for integrated control of an active subcircuit and process for fabrication

(75) Inventors: Bryan Keith Farber, Chandler, AZ (US); Steven James Franson, Scottsdale, AZ (US); John E. Holmes, Scottsdale, AZ (US); Rudy M. Emrick, Gilbert, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL

(21) Appl. No.: 09/909,939

(22) Filed: Jul. 23, 2001

(51) Int. Cl. H01L 29/06; H01L 29/76; H01L 29/94; H01L 31/062; H01L 31/113; H01L 31/119

(52) U.S. Cl. 257/336; 257/28

(57) ABSTRACT

A semiconductor structure for integrated control of an active subcircuit includes a monocrystalline silicon substrate, an amorphous oxide material overlying the monocrystalline silicon substrate, a monocrystalline perovskite oxide material overlying the amorphous oxide material, a monocrystalline compound semiconductor material overlying the monocrystalline perovskite oxide material, the active subcircuit in the monocrystalline compound semiconductor material, and a bias subcircuit in the monocrystalline silicon substrate and electrically coupled to the active subcircuit to bias the active subcircuit.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer comprised of semiconductor material, compound semiconductor material, and/or other types of material such as metals and non-metals, and that further includes an active subcircuit and a bias subcircuit electrically coupled to the active subcircuit to bias the active subcircuit.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Furthermore, bias conditions and thermal issues for a field effect transistor (FET) can cause thermal runaway conditions and/or current imbalances within the FET or between different FETs. These problems degrade the electrical performance of the FET and cause reliability problems, including early failures, for the FET.

For example, a channel or junction temperature of a FET will increase when a FET is either (1) turned on to conduct a large current from its drain, across its channel, to its source or (2) operating under a drain-to-source breakdown condition. As the junction temperature increases, the gate leakage current increases, which produces a voltage drop across an intrinsic resistance in the gate electrode of the FET. As the voltage drop increases, the voltage applied to the gate electrode decreases when, for example, the FET is an n-type depletion mode device. The decrease in applied gate voltage causes more drain-to-source current to flow across the channel of the FET, which causes a further increase the junction temperature and exacerbates the problem. The FET is eventually destroyed by this thermal runaway condition. which can be a significant reliability problem.

Additionally, FETs with larger peripheries and many gate electrodes or fingers may have a disproportionate amount of current flowing across certain channels of the FET causing “hot spots” within these certain channels. If the “hot spots” exceed the maximum junction temperature for the FET, then the FET will also be destroyed, which can magnify the reliability problem.

In a traditional gallium arsenide-based amplifier using a single FET or multiple FETs, an external or off-chip circuit can be electrically connected to the amplifier to bias the amplifier and alleviate some of these reliability problems. The use of these off-chip circuits, however, introduces other problems including an increased part count, larger component size, higher manufacturing complexities, greater cost, and potential interference with the electrical performance of the amplifier.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals. A need also exists for the semiconductor structure to eliminate, or at least reduce, thermal runaway problems and current imbalances of transistors in the semiconductor structure.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of another embodiment of a device structure in accordance with the invention;

FIGS. 21-23 illustrate schematically, in cross section, the formation of a yet another embodiment of a device structure in accordance with the invention;

FIGS. 24 and 25 illustrate schematically, in cross section, device structures that can be used in accordance with various embodiments of the invention;

FIGS. 26-30 illustrate cross-sectional views of a portion of an integrated circuit that includes a compound semiconductor portion, a bipolar portion, and an MOS portion in accordance with what is shown herein;

FIG. 31 illustrates a general block diagram of an embodiment of an active subcircuit and a bias subcircuit electrically coupled to the active subcircuit to bias the active subcircuit in accordance with the invention; FIG. 32 illustrates a more specific block diagram of an embodiment of the active subcircuit and the bias subcircuit of FIG. 31 in accordance with the invention;

FIG. 33 illustrates a circuit diagram of another embodiment of the active subcircuit and the bias subcircuit of FIG. 31 in accordance with the invention;

FIG. 34 illustrates a more specific block diagram of a further embodiment of the active subcircuit and the bias subcircuit of FIG. 31 in accordance with the invention;

FIG. 35 illustrates a top view of an embodiment of a transistor in the active subcircuit of FIG. 31 in accordance with the invention;

FIG. 36 illustrates schematically, in cross-section, an embodiment of a semiconductor device coupled to a support substrate in accordance with the invention;

FIG. 37 illustrates schematically, in cross-section, a different embodiment of a semiconductor device coupled to a support substrate in accordance with the invention;

FIG. 38 illustrates schematically, in cross-section, another embodiment of a semiconductor device coupled to a support substrate in accordance with the invention; and

FIG. 39 illustrates a flow chart for an embodiment of a process of fabricating a semiconductor structure having an active subcircuit and a bias subcircuit in accordance with the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention. Additionally, for simplicity and clarity of illustration, the figures illustrate the general manner of construction, and descriptions and details of well-known features and techniques are omitted to avoid unnecessarily obscuring the invention. Furthermore, the terms first, second, third, fourth, and the like in the description and in the claims, if any, are (1) used for distinguishing between similar elements and not necessarily for describing a sequential or chronological order and (2) interchangeable under appropriate circumstances such that the embodiments of the invention described herein are, for example, capable of operation in other sequences than described or illustrated herein. Moreover, the terms top, bottom, over, under, and the like in the description and in the claims, if any, are (1) used for descriptive purposes, (2) not necessarily for describing permanent relative positions, and (3) interchangeable under appropriate circumstances such that the embodiments of the invention described herein are, for example, capable of operation in other orientations than described or illustrated herein.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, an accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous interface layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous interface layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group W of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous interface layer 28 is grown on substrate 22 at the interface between substrate 22 and the growing accommodating buffer layer by the oxidation of substrate 22 during the growth of layer 24. The amorphous interface layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous interface layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template layer 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

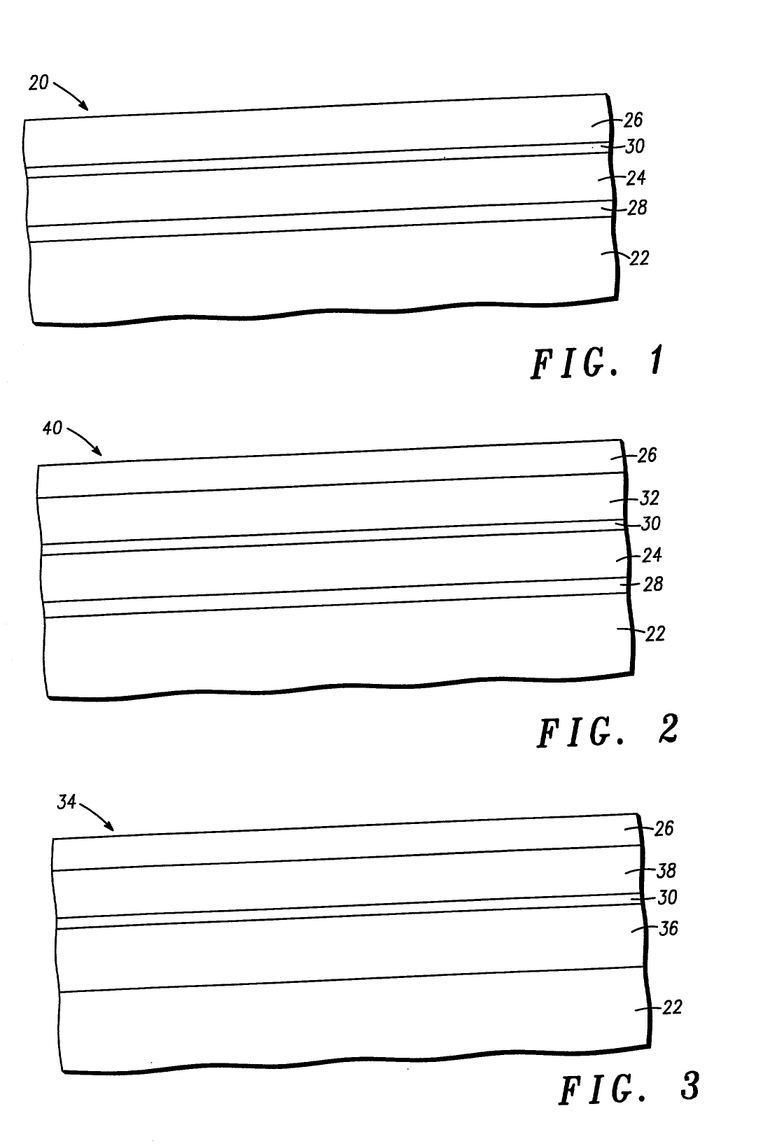

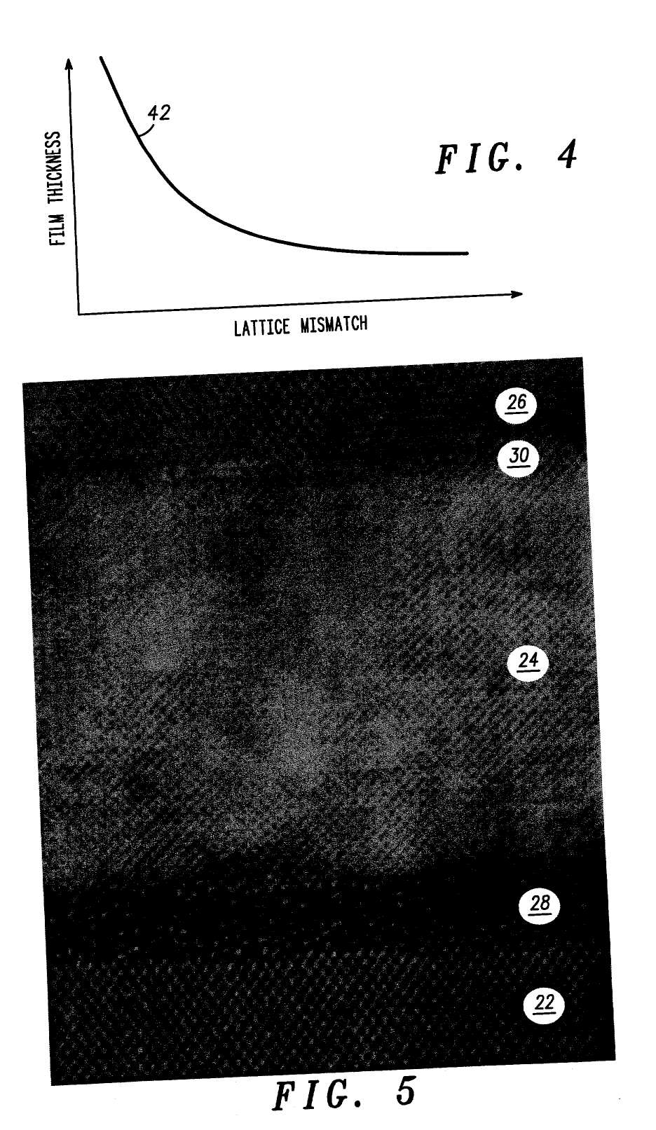

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between substrate 22 and layer 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 millimeters (mm). In accordance with this embodiment of the invention, accommodating buffer layer 24 is a monocrystalline layer of Sr_{z}Ba_{1-z}TiO₃ where z ranges from 0 to 1 and the amorphous interface layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous interface layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous interface layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about is 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or bariumoxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1 -10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ, superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### Example 5

This example also illustrates materials useful in a structure 40 as illustrated in FIG. 2. Substrate 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate 22, template layer 30, and monocrystalline material layer 26 may be the same as those described above in connection with example 1.

Amorphous layer 36 is an amorphous oxide layer which is suitably formed of a combination of amorphous interface layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide interface layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interface layer 28 is formed which relieves strain due to lattice mismatch. GaAs compound semiconductor layer 26 was then grown epitaxially using template layer 30.

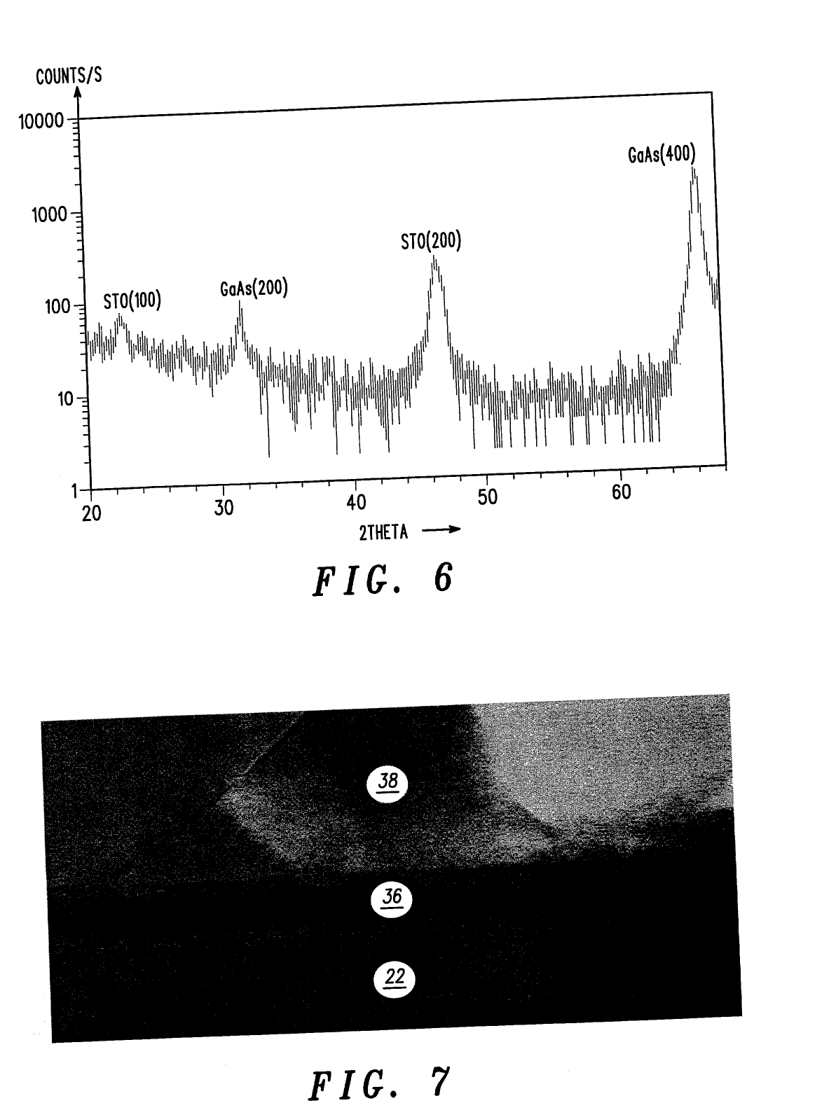

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing monocrystalline layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor material in layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

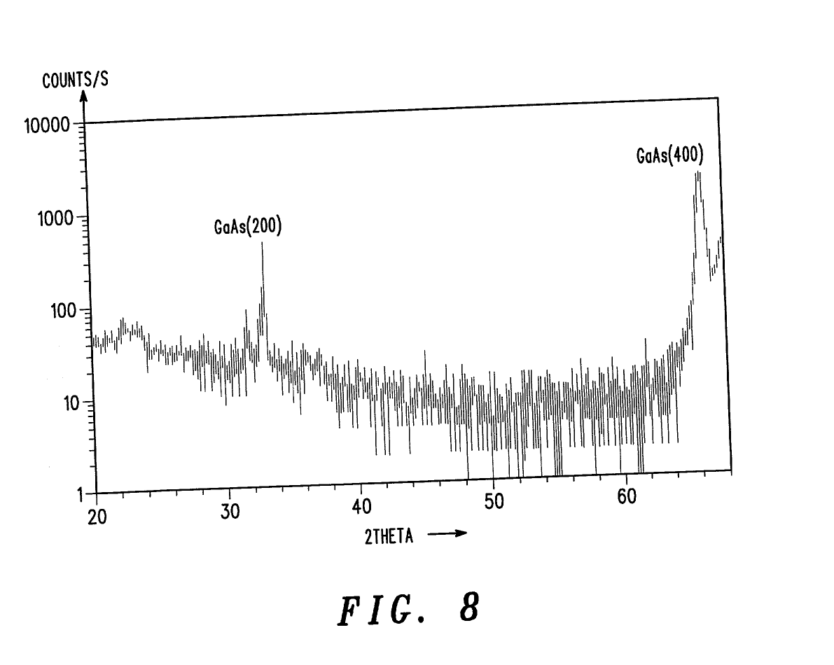

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous interface layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

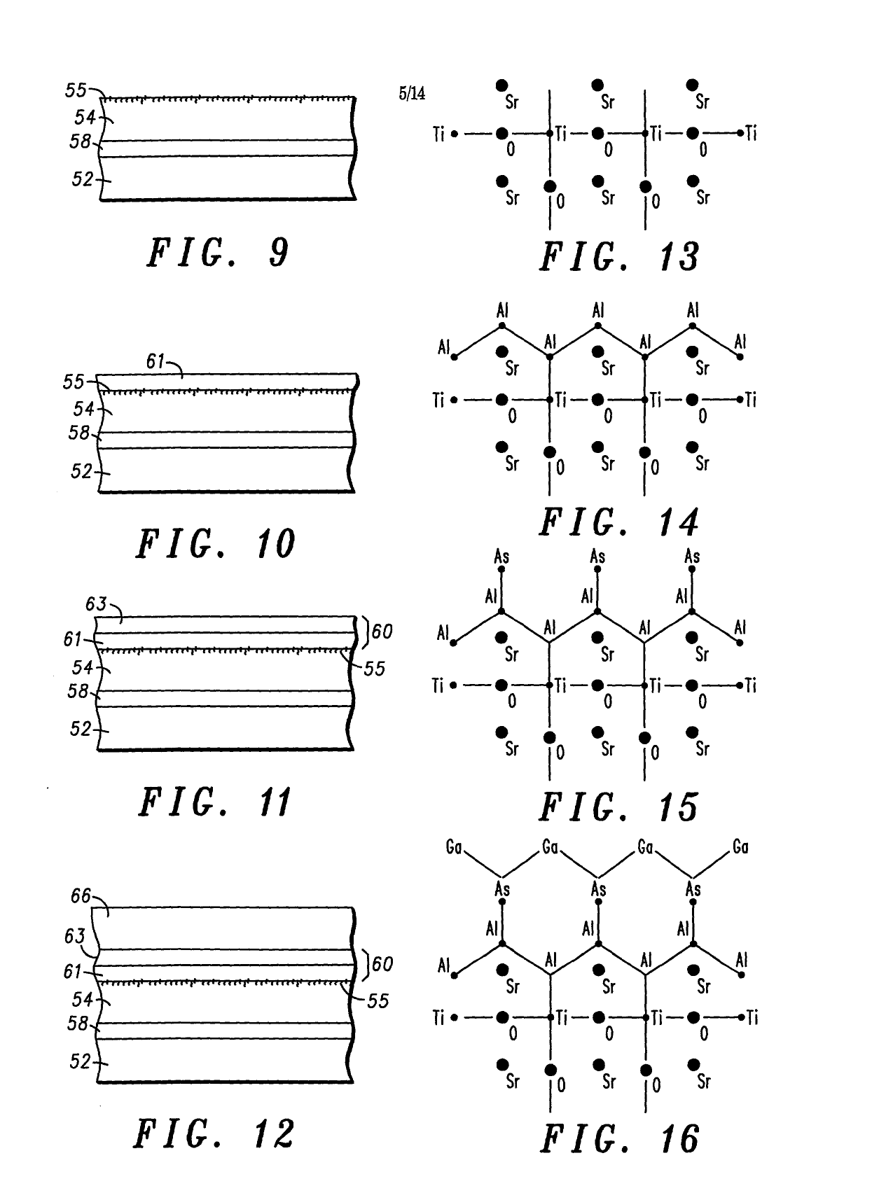

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layer 28 and substrate 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

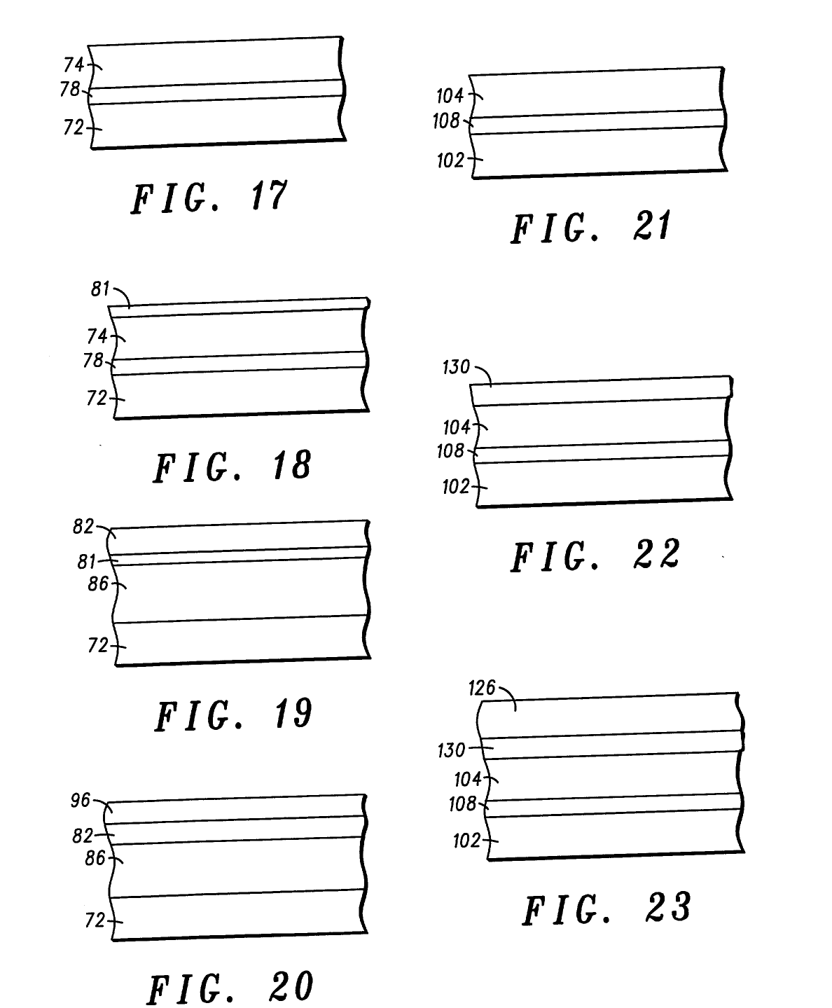

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an interface single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

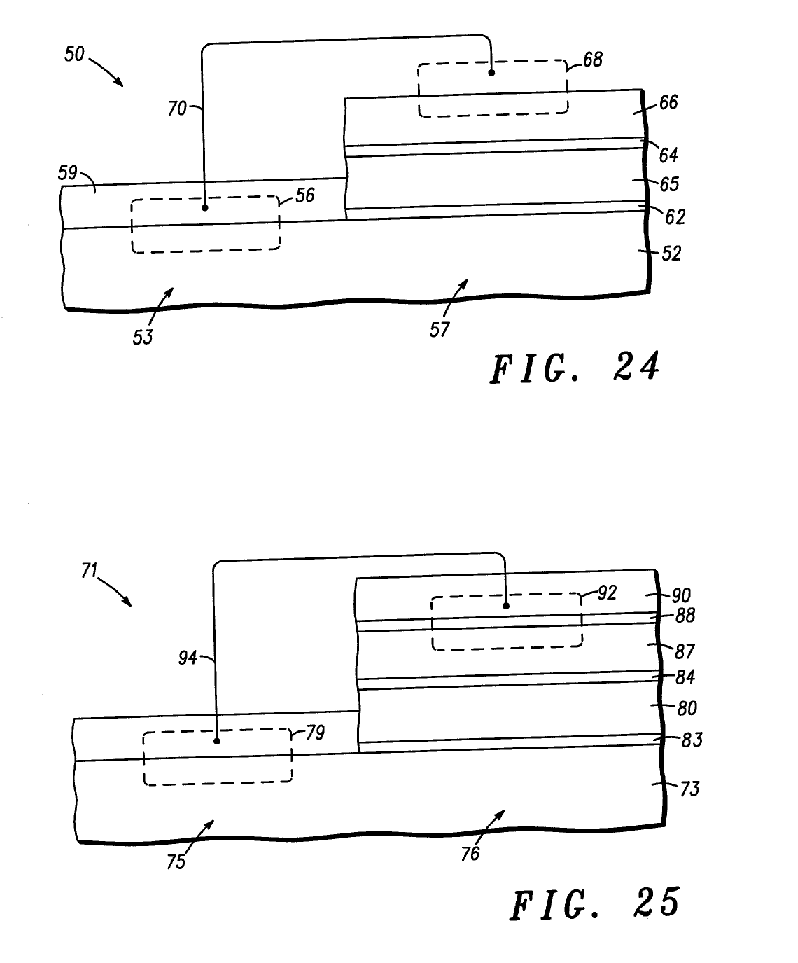

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a passive device such as, for example, a resistor, a capacitor, an inductor, or an antenna; an active semiconductor component such as, for example, a diode or a transistor; or an integrated circuit such as, for example, a CMOS or BiCMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of a region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer 62 of silicon oxide on region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide for layer 66. Alternatively, strontium can be substituted for barium in the above example.

In accordance with a further embodiment, a semiconductor component, generally indicated by a dashed line 68 is formed, at least partially, in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple component 68 and component 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed, at least partially, in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed, at least partially, in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

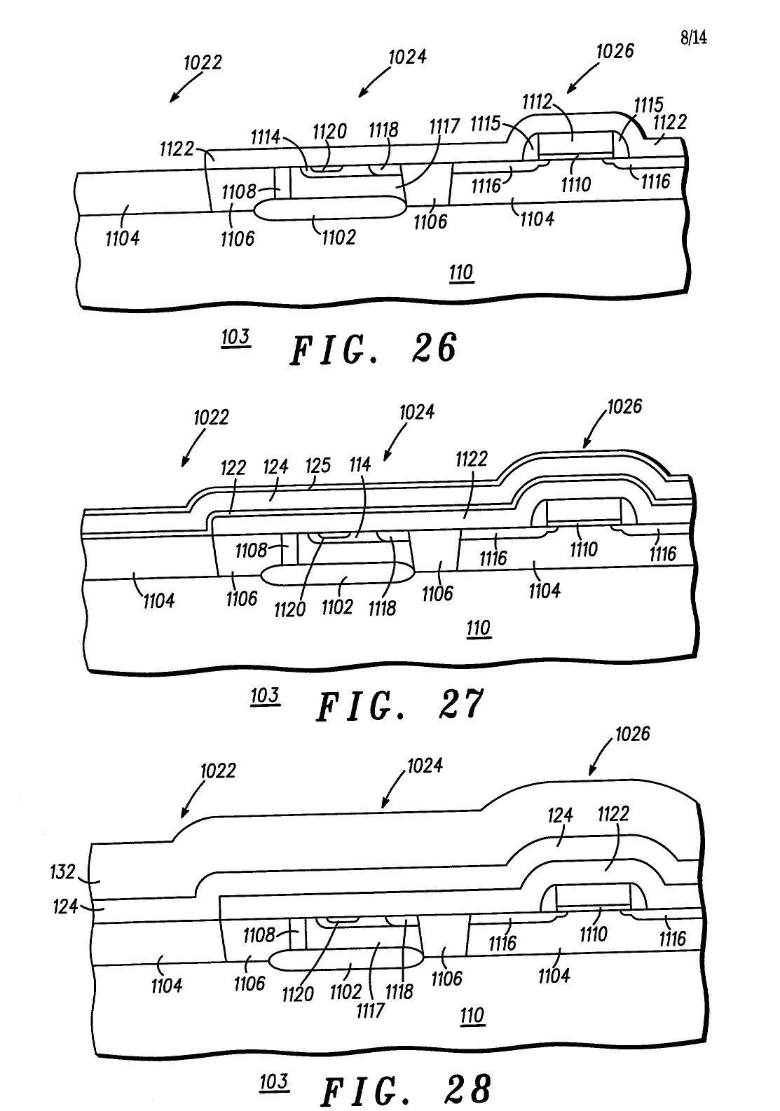

Attention is now directed to a method for forming exemplary portions of illustrative composite semiconductor structures or composite integrated circuits like structure 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector. region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

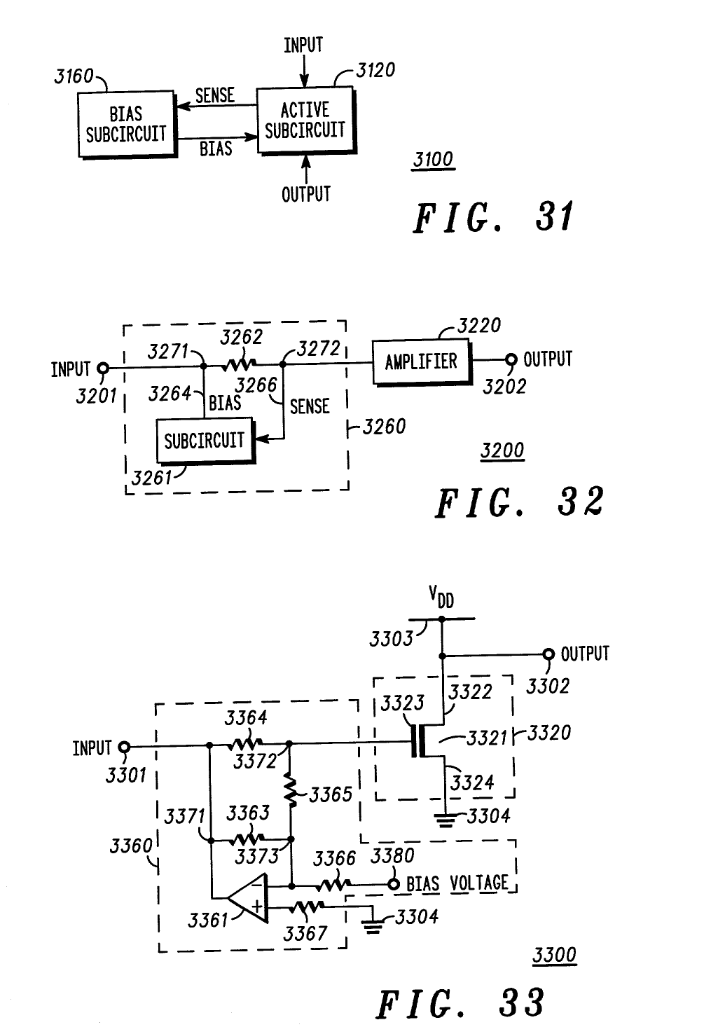

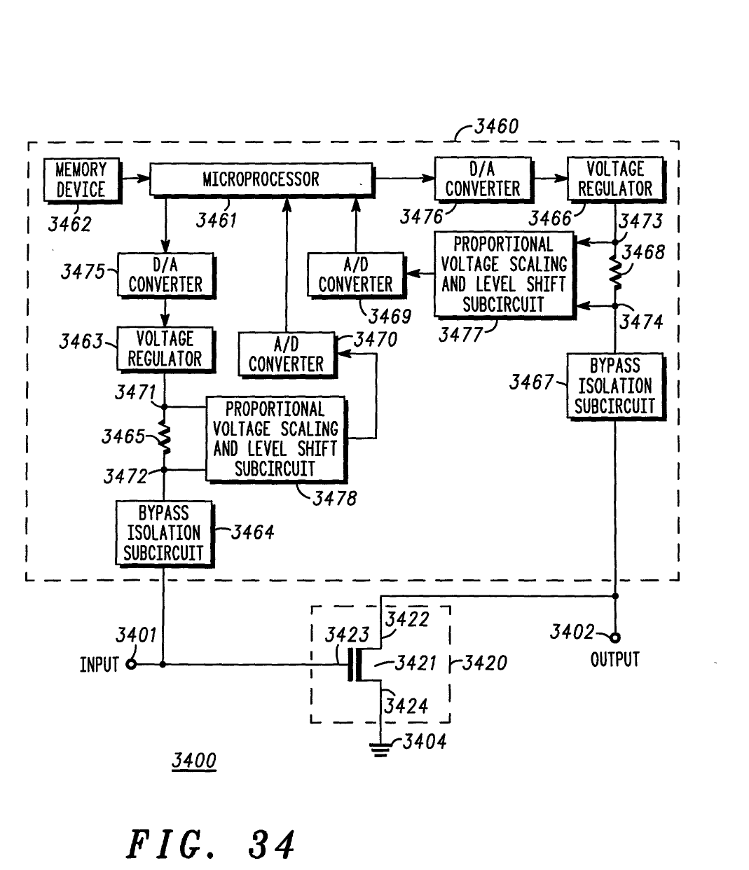

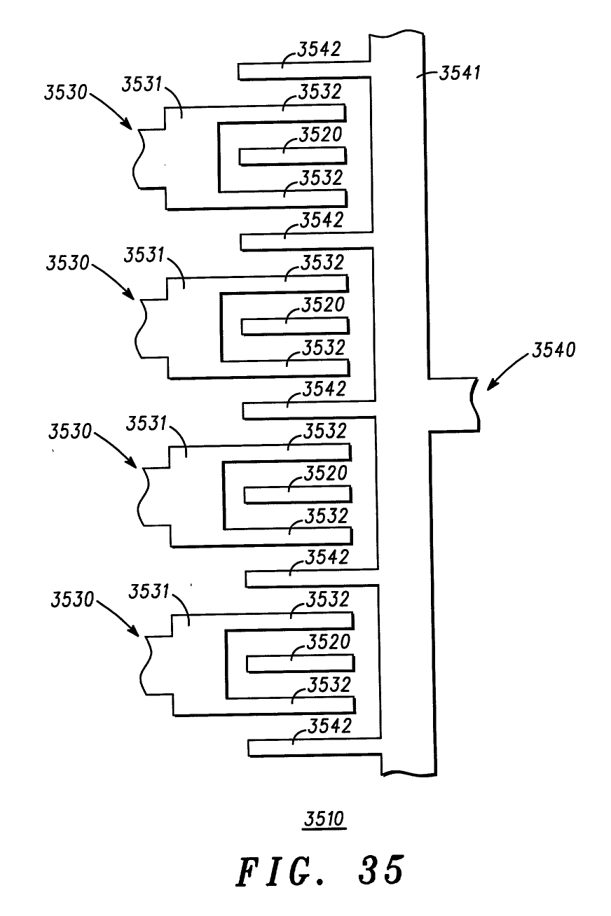

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The monocrystalline compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove removing portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

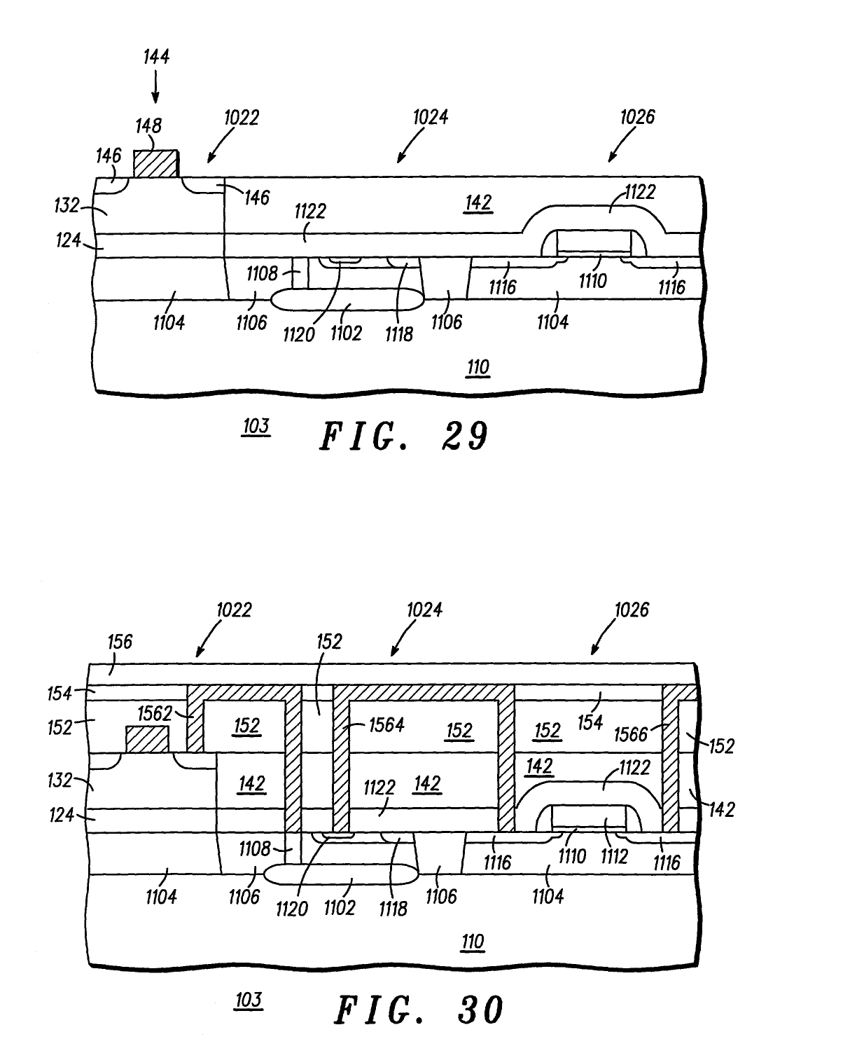

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103. Electrical contacts such as, for example, wire bonding pads and flip-chip bumps, can be also be formed, as desired.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

The semiconductor structures and processes described hereinabove can be used to integrate an active subcircuit and a bias subcircuit onto different portions of a single semiconductor structure or chip. The active and bias subcircuit s are electrically coupled together to maximize the electrical performance of the active subcircuit while maintaining or otherwise operating a current or currents in a device or portion of a device in the active subcircuit at safe and reliable levels. More specifically, the bias subcircuit biases or controls the active subcircuit to, for example, prevent thermal runaway conditions and/or current imbalances from occurring within the active subcircuit. As an example, the bias subcircuit can be electrically coupled to the active subcircuit in a sense and feedback loop to bias a portion of the active subcircuit. The bias subcircuit can be referred to as a driver circuit or a matching circuit, depending upon its function. Formed by the electrical coupling together of the active and bias circuits, the resulting integrated circuit can be considered a self-biased or self-regulating integrated circuit. The bias circuit can be used to switch between different operating points, such as optimum gain, optimum power, optimum noise performance, and optimum Third Order Intercept (TOI).

The close proximity of the active and bias circuits with each other eliminates, or at least reduces, the need for any external electrical connections to the active circuit to appropriately bias and protect the active circuit from excessive junction temperatures. Thus, any interference with the performance of the active circuit caused by such external electrical connections can be minimized. One skilled in the art will also understand that the active and bias subcircuits described herein may also be manufactured in other semiconductor structures than those described herein.

As an example, FIG. 31 illustrates a block diagram of an embodiment of an integrated circuit 3100 comprising an active subcircuit 3120 and a bias subcircuit 3160 electrically coupled to active subcircuit 3120 to bias active subcircuit 3120. Active subcircuit 3120 receives an input signal, preferably a high frequency or Radio Frequency (RF) input signal, and generates an output signal, preferably a high frequency or RF output signal. Bias subcircuit 3160 senses a characteristic of active subcircuit 3120 via a sense line, and in response to the characteristic, bias subcircuit 3160 feeds a control signal back to active subcircuit 3120 or biases active subcircuit 3120, via a bias line, to change the characteristic.

As an example, the characteristic can be a voltage, a current, a temperature, or an output power of active subcircuit 3120. For instance, the characteristic can be any, or all, of the following: (1) a drain voltage of a FET in active subcircuit 3120; (2) a gate current of a FET in active subcircuit 3120, which can be converted into a voltage; (3) a temperature near a channel of a FET in active subcircuit 3120 to estimate the junction temperature of the FET; and (4) an output power of a FET in active subcircuit 3120. One skilled in the art will understand that active subcircuit 3120 can alternatively or additionally comprise a bipolar transistor and that similar characteristics of the bipolar transistor can be sensed and biased by bias subcircuit 3160.

Active subcircuit 3120 can consist of a single transistor or can comprise multiple transistors. The transistors can be bipolar transistors including HBTs, FETs including MESFETs, and/or High Electron Mobility Transistors (HEMTs). Active subcircuit 3120 can also optionally comprise other active devices such as diodes, and active subcircuit 3120 can further optionally comprise at least one passive device such as a resistor, diode, capacitor, inductor, and/or transmission line. The actual circuit or circuits used in active subcircuit 3120 can be known in the art, but the on-chip integration of such circuit or circuits with bias subcircuit 3160 is novel.

As an example, the active device(s) and the optional passive device(s) of active subcircuit 3120 can form a single stage or multi-stage amplifier. If active subcircuit 3120 comprises a single-stage amplifier having a single transistor, bias subcircuit 3160 can bias a single portion or multiple portions of the transistor in the same or different manners. If active subcircuit 3120 comprises a single-stage amplifier having multiple transistors, bias subcircuit 3160 can bias a single portion or multiple portions of a single transistor or multiple transistors in the same or different manners. If active subcircuit 3120 comprises a multi-stage amplifier, bias subcircuit 3160 can bias a single portion or multiple portions of a single transistor or multiple transistors in a single stage or multiple stages of the amplifier in the same or different manners. Accordingly, bias subcircuit 3160 can bias different portions of active subcircuit 3120 in the same or different manners.

Bias subcircuit 3160 can comprise a variety of subcircuits to achieve its function. As an example, bias subcircuit 3160 can consist solely of or can comprise at least an operational amplifier and/or a voltage regulator with an optional bypass or isolation circuit. Bias subcircuit 3160 can also comprise a microprocessor to control the operational amplifier, voltage regulator, and/or bypass or isolation circuit. In addition to the microprocessor, bias subcircuit 3160 can further comprise a separate memory device. As an example, the memory device can comprise a Random Access is Memory (RAM), a Read-Only Memory (ROM), or a flash memory. As another example, the microprocessor can be a microcontroller, in which case the separate memory device is not required. The actual circuit or circuits used in bias subcircuit 3160 can be known in the art, but the on-chip integration of such circuit or circuits with active subcircuit 3120 is novel.

Active subcircuit 3120 and bias subcircuit 3160 can be part of a semiconductor structure formed in a composite substrate similar to that described hereinbefore. For example, the composite substrate can comprise at least a monocrystalline silicon substrate, an amorphous oxide material overlying the monocrystalline silicon substrate, a monocrystalline perovskite oxide material overlying the amorphous oxide material, and a monocrystalline compound semiconductor material overlying the monocrystalline perovskite oxide material. The substrate and materials have already been described in detail.

As an example, active subcircuit 3120 and bias subcircuit 3160 can be integrated together onto the composite substrate in a Monolithic Microwave Integrated Circuit (MMIC). At least portions of active subcircuit 3120 and bias subcircuit 3160 are located in and over the monocrystalline compound semiconductor material and the monocrystalline silicon substrate, respectively. In some applications, active subcircuit 3120 may need to operate at a higher frequency than bias subcircuit 3160. Accordingly, in some embodiments, active subcircuit 3120 is located in only the monocrystalline compound semiconductor material and is not located in the monocrystalline silicon substrate to maximize the high frequency operation of active subcircuit 3120. Also in these embodiments, bias subcircuit 3160 is located in and over only the monocrystalline silicon substrate and is not located in or over the monocrystalline compound semiconductor material to reduce the cost of integrated circuit 3100 and to improve the heat dissipation efficient for bias subcircuit 3160. In other embodiments, however, a portion of active subcircuit 3120 can be located in and over the monocrystalline silicon substrate, and a portion of bias subcircuit 3160 can be located in and over the monocrystalline compound semiconductor material.

FIG. 32 illustrates a block diagram of an embodiment of the active and bias subcircuits of FIG. 31. In particular, FIG. 32 illustrates an integrated circuit 3200 comprising an active subcircuit 3220 and a bias subcircuit 3260 electrically coupled to active subcircuit 3220 to bias active subcircuit 3220. In the preferred embodiment, active subcircuit 3220 is an amplifier. Integrated circuit 3200 also comprises an input 3201 and an output 3202.

Bias subcircuit 3260 comprises a subcircuit 3261, a resistor 3262, a sense line 3266, a bias line 3264, and nodes 3271 and 3272. Resistor 3262 is coupled to subcircuit 3261 via node 3271 and sense line 3266 and also via node 3272 and bias line 3264. Active subcircuit 3220 is coupled to bias subcircuit 3260 at node 3272. Input 3201 is coupled to bias subcircuit 3260 at node 3271 and is coupled to active subcircuit 3220 via bias subcircuit 3260. Output 3202 is coupled to active subcircuit 3220.

Active subcircuit 3220 receives an input signal from input 3201 and generates an output signal at output 3202. Bias subcircuit 3160 senses a characteristic of active subcircuit 3220 via sense line 3266, and in response to the characteristic, bias subcircuit 3260 feeds a control signal back to active subcircuit 3220 or biases active subcircuit 3220, via bias line 3264, to change the characteristic.

FIG. 33 illustrates a circuit diagram of another embodiment of the active and bias subcircuits of FIG. 31. In particular, FIG. 33 illustrates an integrated circuit 3300 comprising an active subcircuit 3320 and a bias subcircuit 3360 electrically coupled to active subcircuit 3320 to bias active subcircuit 3320. In the preferred embodiment, active subcircuit 3320 is an amplifier. Integrated circuit 3300 also comprises an input 3301, an output 3302, a voltage source (VDD) 3303, and a ground potential 3304.

Bias subcircuit 3360 comprises an operational amplifier 3361, resistors 3363, 3364, 3365, 3366, and 3367, a bias voltage 3380, and nodes 3371, 3372, and 3373. Operational amplifier 3361 comprises an output coupled to node 3371, a positive input coupled to resistor 3367, and a negative input coupled to node 3373. Resistors 3363, 3365, and 3366 are also coupled to node 3373, and resistors 3363 and 3365 are further coupled to nodes 3371 and 3372, respectively. Resistor 3364 is coupled between nodes 3371 and 3372. Input 3301 is coupled to bias subcircuit 3360 at node 3371 and is coupled to active subcircuit 3320 via bias subcircuit 3360.

Active subcircuit 3320 comprises a transistor 3321, which in the preferred embodiment is a HEMT or HBT. Transistor 3321 comprises a drain terminal 3322, a gate terminal 3323, and a source terminal 3324. Drain terminal 3322 is coupled to voltage source 3303 and output 3302, and source terminal 3324 is coupled to ground potential 3304. Gate terminal 3323 is coupled to bias subcircuit 3360 at node 3372.

In bias subcircuit 3360, resistor 3365 is referred to as a sense resistor and can be approximately one to one thousand ohms. Resistors 3366 and 3367 are referred to as set point or bias resistors and can each be approximately one to one thousand ohms. Resistor 3363 is referred to as a feedback resistor and can have a value dependent upon the desired gain for operational amplifier 3361. The gain of amplifier 3361 is proportional to the ratio between resistor 3363 and resistors 3366 and 3367.

In bias subcircuit 3360, resistor 3364 can be approximately one to one hundred ohms. In a different embodiment, resistor 3364 can be a portion of active subcircuit 3320. For example, resistor 3364 can represent an intrinsic resistance of gate terminal 3323 or a resistor in series with gate terminal 3323. Regardless of which embodiment for resistor 3364 is used, resistors 3364 and 3365 can be located in or over, for example, the monocrystalline compound semiconductor substrate and/or the monocrystalline silicon substrate.

Active subcircuit 3320 receives an input signal from input 3301 and generates an output signal at output 3302. Bias subcircuit 3360 senses a characteristic of a portion of active subcircuit 3320 and in response to the characteristic, bias subcircuit 3360 feeds a control signal back to a portion of active subcircuit 3320 or biases a portion of active subcircuit 3320 to change the characteristic. For example, bias subcircuit 3360 can sense a characteristic at one of the electrical terminals of transistor 3321 and, in response thereto, can bias one of the electrical terminals of transistor 3321. As illustrated in FIG. 33, by adding resistors coupled to gate terminal 3323 to sense the actual voltage being applied to gate terminal 3323, active bias subcircuit 3360 can apply various bias conditions to transistor 3321 to prevent a thermal runaway condition. This electrical configuration creates a more robust design resulting in higher reliability for integrated circuit 3300. One skilled in the art will understand that active subcircuit 3320 can comprise multiple transistors, only one of which or more than one of which can be biased in a manner similar to that described for transistor 3321.

FIG. 34 illustrates a block diagram of a further embodiment of the active and bias subcircuits of FIG. 31. In particular, FIG. 34 illustrates an integrated circuit 3400 comprising an active subcircuit 3420 and a bias subcircuit 3460 electrically coupled to active subcircuit 3420 to bias active subcircuit 3420. In the preferred embodiment, active subcircuit 3420 is an amplifier. Integrated circuit 3400 also comprises an input 3401, an output 3402, and a ground potential 3404.

Bias subcircuit 3460 comprises a microprocessor 3461, a memory device 3462, voltage regulators 3463 and 3466, bypass or isolation subcircuits 3464 and 3467, digital-to-analog (D/A) converters 3475 and 3476, analog-to-digital (A/D) converters 3469 and 3470, proportional voltage scaling and level shifting subcircuits 3477 and 3478, resistors 3465 and 3468, and nodes 3471, 3472, 3473, and 3474. Memory device 3462 is coupled to microprocessor 3461, which collectively can represent a microcontroller. Microprocessor 3461 has inputs coupled to the outputs of A/D converters 3469 and 3470, and microprocessor 3461 has outputs coupled to the inputs of D/A converters 3475 and 3476. D/A converters 3475 and 3476 have outputs coupled to voltage regulators 3463 and 3466.

Although not illustrated in FIG. 34, microprocessor 3461 can also have outputs coupled to bypass or isolation subcircuits 3464 and 3467 and/or proportional voltage scaling and level shifting subcircuits 3477 and 3478 to control bypass or isolation subcircuits 3464 and 3467 and/or proportional voltage scaling and level shifting subcircuits 3477 and 3478.

Voltage regulators 3463 and 3466 can be of a programmable type and can comprise D/A converters, in which case the outputs of microprocessor 3461 can be coupled directly to voltage regulators 3463 and 3466. Additionally, microprocessor 3461 can comprise D/A converters, in which the outputs of microprocessor 3461 can be coupled directly to voltage regulators 3463 and 3466. Furthermore, microprocessor 3461 can also comprise A/D converters, in which case the inputs of microprocessor 3461 can be coupled directly to proportional voltage scaling and level shifting subcircuits 3477 and 3478.

Voltage regulators 3463 and 3466 are coupled to nodes 3471 and 3473, respectively. Bypass or isolation subcircuits 3464 and 3467 are coupled to nodes 3472 and 3474, respectively. Resistor 3465 is coupled between nodes 3471 and 3472, and resistor 3468 is coupled between nodes 3473 and 3474. Proportional voltage scaling and level shifting subcircuits 3477 and 3478 can each comprise an operational amplifier and resistors to provide a proportional voltage from nodes 3473 and 3474 and from 3471 and 3472 to A/D converters 3469 and 3470.

Input 3401 is coupled to bias subcircuit 3460, particularly bypass or isolation subcircuit 3464. Input 3401 is also coupled to active subcircuit 3420. Output 3402 is coupled to bias subcircuit 3460, particularly bypass or isolation subcircuit 3467. Output 3402 is also coupled to active subcircuit 3420.

Active subcircuit 3420 comprises a transistor 3421, which in the preferred embodiment is a HEMT or HBT. Transistor 3421 comprises a drain terminal 3422, a gate terminal 3423, and a source terminal 3424. Drain terminal 3422 is coupled to output 3402 and to bias subcircuit 3460, particularly bypass or isolation subcircuit 3467. Source terminal 3424 is coupled to ground potential 3404, and gate terminal 3423 is coupled to input 3401 and bias subcircuit 3460, particularly bypass or isolation subcircuit 3464.

In bias subcircuit 3460, resistor 3465 has a larger resistance than resistor 3468 because of the smaller currents at gate terminal 3423 than at drain terminal 3422 of transistor 3421. For example, resistor 3465 can be approximately one to one hundred ohms, and resistor 3468 can be less than or equal to approximately one ohm. Resistors 3465 and 3468 can be located in and/or over the monocrystalline silicon substrate and/or the monocrystalline compound semiconductor material.

Proportional voltage scaling and level shifting subcircuits 3477 and 3478 are coupled to resistors 3468 and 3465, sense a voltage proportional to a current conducted across resistors 3468 and 3465, and translate or scale the voltage to a voltage level suitable for the inputs of A/D converters 3469 and 3470.

Bypass or isolation subcircuits 3464 and 3467 couple resistors 3465 and 3468, respectively, to gate terminal 3423 and drain terminal 3422, respectively. Bypass or isolation subcircuits 3464 and 3467 can comprise shunt capacitors, inductors, and the like. Bypass or isolation subcircuits 3464 and 3467 are optional and can be removed from bias subcircuit 3460, in which case resistors 3465 and 3468 can be coupled directly to gate terminal 3423 and drain terminal 3422 of transistor 3421 via nodes 3472 and 3474. Voltage regulators 3463 and 3466 can be programmable and can be turned-off when desired.

Active subcircuit 3420 receives an input signal from input 3401 and generates an output signal at output 3402. Bias subcircuit 3460 senses characteristics of portions of active subcircuit 3420 and in response to the characteristics, bias subcircuit 3460 feeds control signals back to portions of active subcircuit 3420 or biases portions of active subcircuit 3420 to change the characteristics. For example, bias subcircuit 3460 can sense separate characteristics at two of the electrical terminals of transistor 3421 and, in response thereto, can separately bias two of the electrical terminals of transistor 3421. As illustrated in FIG. 34, by adding resistors coupled to gate terminal 3423 and drain terminal 3422 to sense the actual voltages being applied to gate terminal 3423 and drain terminal 3422, active bias subcircuit 3460 can use voltage regulators 3463 and 3466 to separately apply various bias conditions to gate terminal 3423 and drain terminal 3422 of transistor 3421 to prevent a thermal runaway condition. This feature creates a more robust design resulting in higher reliability for integrated circuit 3400. One skilled in the art will understand that active subcircuit 3420 can comprise multiple transistors, only one of which or more than one of which can be biased in a manner similar to that described for transistor 3421.

FIG. 35 illustrates a top view of an embodiment of a transistor in the active subcircuit of FIG. 31. In particular, FIG. 35 illustrates a transistor 3510. Transistor 3510 can also be similar to transistors 3321 and 3421 in FIGS. 33 and 34.

Transistor 3510 in FIG. 35 has a large periphery with a large number of gate fingers or electrodes coupled to separate gate terminals. For example, transistor 3510 comprise gate terminals 3530, which can be electrically biased separately from each other. Each of gate terminals 3530 comprise a gate bus 3531 and gate electrodes 3532 coupled to gate bus 3531.

Transistor 3510 also comprises a source terminal 3540 having a source bus 3541 and source fingers or electrodes 3542 coupled to source bus 3541. Transistor 3510 further comprises a drain terminal (not shown in FIG. 35) having a drain bus (not shown in FIG. 35) coupled to drain fingers or electrodes 3520. Each of gate electrodes 3532 are interdigitated between an immediately adjacent one of source electrodes 3542 and an immediately adjacent one of drain electrodes 3520.

The bias subcircuits described earlier with reference to FIGS. 31, 32, 33, and 34 can be used to sense and bias gate voltages or currents separately for each of gate terminals 3530 in FIG. 35. In this manner, the currents conducted across different channels within transistor 3510 can be balanced. Alternatively, the bias subcircuits can be used to sense and bias gate voltage or currents for only some of gate terminals 3530. In particular, only the central or non-peripheral ones of gate terminals 3530 can be sensed and biased because typically only the central or non-peripheral channels in a large periphery transistor develop the problematic “hot spots” described earlier.

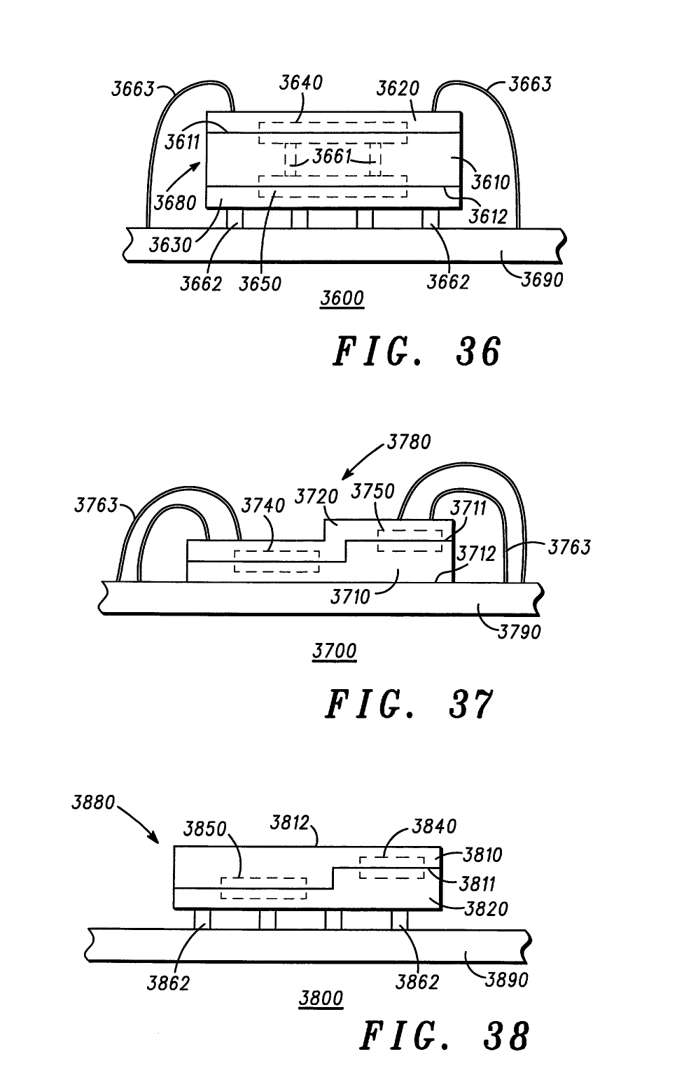

FIG. 36 illustrates schematically, in cross-section, an embodiment of a semiconductor structure 3600 comprising a semiconductor device 3680 coupled to a support substrate 3690. Semiconductor device 3680 comprises a composite substrate 3610 having at least a monocrystalline silicon substrate, an amorphous oxide material, a monocrystalline perovskite oxide material, and a monocrystalline compound semiconductor material, as described earlier. Composite substrate 3610 has a side 3611 and a side 3612 opposite side 3611. The monocrystalline silicon substrate can form at least a portion of side 3611, and the monocrystalline compound semiconductor material can form at least a portion of side 3612.

Semiconductor device 3680 also comprises a bias subcircuit 3640 located at side 3611 of composite substrate 3610 and an active subcircuit 3650 located at side 3612 of composite substrate 3610. Semiconductor device 3680 additionally comprises electrically conductive vias 3661 coupling together active subcircuit 3650 and bias subcircuit 3640. In one embodiment, electrically conductive vias 3611 can serve as resistors 3364 and 3365 in FIG. 33 or resistors 3465 and 3468 in FIG. 34.

Semiconductor device 3680 further comprises composite layers 3620 and 3630, each of which comprise electrically insulative layers and electrically conductive layers. As an example, composite layer 3620 can include a multi-layer metallization scheme to electrically couple different portions of bias subcircuit 3640 with each other, and composite layer 3630 can electrically couple different portions of active subcircuit 3650 with each other. Composite layer 3620 is located adjacent to side 3611 of composite substrate 3610, and composite layer 3630 is located adjacent to side 3612 of composite substrate 3610.

Semiconductor device 3680 is mounted over support substrate 3690 such that side 3612 of composite substrate 3610 faces towards support substrate 3690 while side 3611 of composite substrate 3610 faces away from substrate 3690. As an example, support substrate 3690 can be a leadframe, a composite chip carrier, or the like.

Semiconductor structure 3600 also comprises flip chip bumps 3662 located adjacent to composite layer 3630 and to side 3612 of composite substrate 3610. Flip chip bumps 3662 electrically couple active subcircuit 3650 to support substrate 3690. Semiconductor structure 3600 further comprises wire bonds 3663 located adjacent to composite layer 3620 and to side 3611 of composite substrate 3610. Wire bonds 3663 electrically couple bias subcircuit 3640 to support substrate 3690.

FIG. 37 illustrates schematically, in cross-section, an embodiment of a semiconductor structure 3700 comprising a semiconductor device 3780 coupled to a support substrate 3790. Semiconductor device 3780 comprises a composite substrate 3710 having at least a monocrystalline silicon substrate, an amorphous oxide material, a monocrystalline perovskite oxide material, and a monocrystalline compound semiconductor material, as described earlier. Composite substrate 3710 has a side 3711 and a side 3712 opposite side 3711. The monocrystalline silicon substrate and the monocrystalline compound semiconductor material can form at least portions of side 3711, and the monocrystalline silicon substrate can form at least a portion of side 3712.

Semiconductor device 3780 also comprises a bias subcircuit 3740 located at side 3711 of composite substrate 3710 and an active subcircuit 3750 located at side 3711 of composite substrate 3710. Semiconductor device 3780 further comprises a composite layer 3720, which comprises electrically insulative layers and electrically conductive layers. As an example, composite layer 3720 can include a multi-layer metallization scheme to electrically couple different portions of bias subcircuit 3740 with each other, different portions of active subcircuit 3750 with each other, and/or portions of bias subcircuit 3740 with portions of active subcircuit 3750. Composite layer 3720 is located adjacent to side 3711 of composite substrate 3710.

Semiconductor device 3780 is mounted over support substrate 3790 such that side 3712 of composite substrate 3710 faces towards support substrate 3790 while side 3711 of composite substrate 3710 faces away from substrate 3790. As an example, support substrate 3790 can be a leadframe, a chip carrier, or the like.

Semiconductor structure 3700 also comprises wire bonds 3763 located adjacent to composite layer 3720 and to side 3711 of composite substrate 3710. Wire bonds 3763 electrically couple bias subcircuit 3740 and active subcircuit 3750 to support substrate 3790.

FIG. 38 illustrates schematically, in cross-section, an embodiment of a semiconductor structure 3800 comprising a semiconductor device 3880 coupled to a support substrate 3890. Semiconductor device 3880 comprises a composite substrate 3810 having at least a monocrystalline silicon substrate, an amorphous oxide material, a monocrystalline perovskite oxide material, and a monocrystalline compound semiconductor material, as described earlier. Composite substrate 3810 has a side 3811 and a side 3812 opposite side 3811. The monocrystalline silicon substrate and the monocrystalline compound semiconductor material can form at least portions of side 3811, and the monocrystalline silicon substrate can form at least a portion of side 3812.

Semiconductor device 3880 also comprises a bias subcircuit 3840 located at side 3811 of composite substrate 3810 and an active subcircuit 3850 located at side 3811 of composite substrate 3810. Semiconductor device 3880 further comprises a composite layer 3820, which comprises electrically insulative layers and electrically conductive layers. As an example, composite layer 3820 can include a multi-layer metallization scheme to electrically couple different portions of bias subcircuit 3840 with each other, different portions of active subcircuit 3850 with each other, and/or portions of bias subcircuit 3840 with portions of active subcircuit 3850. Composite layer 3820 is located adjacent to side 3811 of composite substrate 3810.

Semiconductor device 3880 is mounted over support substrate 3890 such that side 3811 of composite substrate 3810 faces towards support substrate 3890 while side 3812 of composite substrate 3810 faces away from substrate 3890. As an example, support substrate 3890 can be a leadframe, a chip carrier, or the like.

Semiconductor structure 3800 also comprises flip chip bumps 3862 located adjacent to composite layer 3820 and to side 3811 of composite substrate 3810. Flip chip bumps 3862 electrically couple bias subcircuit 3840 and active subcircuit 3850 to support substrate 3890.

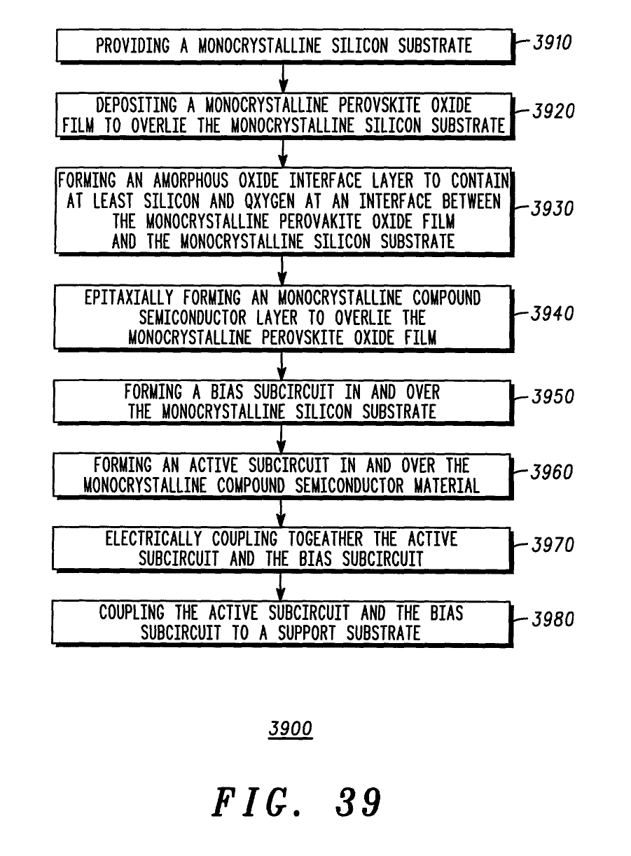

FIG. 39 illustrates a flow chart 3900 for an embodiment of a process of fabricating a semiconductor structure for integrated control of an active subcircuit. At a step 3910 of flow chart 3900, a monocrystalline silicon substrate is provided. Next, at a step 3920, a monocrystalline perovskite oxide film is deposited to overlie the monocrystalline silicon substrate. The film has a thickness less than a thickness of the material that would result in strain-induced defects. Then, at a step 3930, an amorphous oxide interface layer is formed to contain at least silicon and oxygen at an interface between the monocrystalline perovskite oxide film and the monocrystalline silicon substrate. Subsequently, at a step 3940, a monocrystalline compound semiconductor layer is epitaxially formed to overlie the monocrystalline perovskite oxide film.

Next, at a step 3950 of flow chart 3900, a bias subcircuit is formed in and over the monocrystalline silicon substrate, and at a step 3960, an active subcircuit is formed in and over the monocrystalline compound semiconductor layer. As explained earlier, the bias and active subcircuits can be formed in the same or different sides of the composite substrate. Then, at a step 3970, the active subcircuit and the bias subcircuit are individually or collectively electrically coupled together. Subsequently, at a step 3980, the active subcircuit and the bias subcircuit are coupled to a support substrate. As also explained earlier, the coupling of the active and bias subcircuits to the support substrate can include mounting the composite substrate to the support substrate, flip chip bonding, and/or wire bonding.

The details of the steps in flow chart 3900 have already been described, and variations of the steps in flow chart 3900 can include, but are not limited to, the following examples. For instance, between steps 3940 and 3950, portions of the monocrystalline compound semiconductor layer of step 3940, the monocrystalline perovskite oxide film of step 3920, and the amorphous oxide interface layer of step 3930 can be sequentially etched to expose a portion of the monocrystalline silicon substrate in and over which the bias subcircuit is formed in step 3950. As another example, between steps 3910 and 3920, a portion of the monocrystalline silicon substrate can be etched to form a recess in the monocrystalline silicon substrate, and then steps 3920, 3930, and 3940 can be performed to fill the recess, regardless of whether selective or blanket deposition or epitaxial forming processes for steps 3920 and 3940 are used.

In a different variation, step 3960 can be performed before step 3950 and after step 3940. In another variation, step 3950 can be performed after step 3910 and before steps 3920, 3930, and 3940. In this different variation, the monocrystalline compound semiconductor layer of step 3940 can be formed selectively or as a continuous layer over all of the monocrystalline silicon substrate. Alternatively, the monocrystalline compound semiconductor layer of step 3940 can be formed selectively or as a continuous layer over all of the monocrystalline silicon substrate after step 3930 and before performing steps 3950, 3960, 3970, and 3980.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor structure for integrated control of an active subcircuit comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
the active subcircuit at least partially in the monocrystalline compound semiconductor material; and
a bias subcircuit at least partially in the monocrystalline silicon substrate and electrically coupled to the active subcircuit to bias the active subcircuit.

2. The semiconductor structure of claim 1 wherein:
the bias subcircuit is electrically coupled to the active subcircuit in a sense and feedback loop.

3. The semiconductor structure of claim 1 wherein:
the active subcircuit consists of a transistor.

4. The semiconductor structure of claim 1 wherein:
the active subcircuit comprises transistors.

5. The semiconductor structure of claim 1 wherein:
the active subcircuit comprises:
active devices; and
at least one passive device.

6. The semiconductor structure of claim 1 wherein:
the bias subcircuit comprises an operational amplifier.

7. The semiconductor structure of claim 1 wherein:
the bias subcircuit comprises a microprocessor.

8. The semiconductor structure of claim 7 wherein:
the bias subcircuit further comprises a memory device.

9. The semiconductor structure of claim 1 wherein:
the bias subcircuit comprises a voltage regulator.

10. The semiconductor structure of claim 1 wherein:
the bias subcircuit senses a characteristic of the active subcircuit; and
in response to sensing the characteristic, the bias subcircuit biases the active subcircuit to change the characteristic.

11. The semiconductor structure of claim 1 wherein:
the bias subcircuit biases only a portion of the active subcircuit.

12. The semiconductor structure of claim 11 wherein:
the active subcircuit comprises a field effect transistor having gate electrodes; and
the portion of the active subcircuit consists of a portion of the gate electrodes.

13. The semiconductor structure of claim 12 wherein:
the active subcircuit consists of the field effect transistor.

14. The semiconductor structure of claim 11 wherein:
the active subcircuit comprises transistors; and
the portion of the active subcircuit consists of a portion of the transistors.

15. The semiconductor structure of claim 1 wherein:
the monocrystalline silicon substrate, the amorphous oxide material, the monocrystalline perovskite oxide material, and the monocrystalline compound semiconductor material form a composite substrate having a first side and a second side opposite the first side;
the active subcircuit is located at the second side of the composite substrate; and
the bias subcircuit is located at the first side of the composite substrate.

16. The semiconductor structure of claim 15 further comprising:
flip chip bumps located adjacent to the second side of the composite substrate;
wire bonds located adjacent to the first side of the composite substrate; and
a support substrate electrically coupled to the flip chip bumps and the wire bonds,
wherein:
the composite substrate is mounted over the support substrate; and
the second side of the composite substrate faces towards the support substrate.

17. The semiconductor structure of claim 1 where in:
the monocrystalline silicon substrate, the amorphous oxide material, the monocrystalline perovskite oxide material, and the monocrystalline compound semiconductor material form a composite substrate having a first side and a second side opposite the first side;
the active subcircuit is located at the second side of the composite substrate; and
the bias subcircuit is located at the second side of the composite substrate.

18. The semiconductor structure of claim 1 wherein:
a portion of the bias subcircuit is located over the monocrystalline compound semiconductor material.

19. An integrated circuit comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
an active subcircuit at least partially in and over the monocrystalline compound semiconductor material; and
a bias subcircuit at least partially in and over the monocrystalline silicon substrate and electrically coupled to the active subcircuit,
wherein:
the active subcircuit comprises a transistor having electrical terminals;
the bias subcircuit comprises a voltage regulator electrically coupled to a first one of the electrical terminals of the transistor;
the bias subcircuit senses a characteristic at the first one of the electrical terminals of the transistor; and
in response to sensing the characteristic, the bias subcircuit uses the voltage regulator to bias the first one of the electrical terminals of the transistor to change the characteristic.

20. The integrated circuit of claim 19 wherein:
the bias subcircuit further comprises:
a bypass subcircuit electrically coupling together the voltage regulator and the first one of the electrical terminals of the transistor.

21. The integrated circuit of claim 19 wherein:
a portion of the bias subcircuit is located over the monocrystalline compound semiconductor material.

22. The integrated circuit of claim 19 wherein:
the first one of the electrical terminals of the transistor is a gate terminal of the transistor.

23. The integrated circuit of claim 19 wherein:
the electrical terminals of the transistor comprises gate terminals; and
the first one of the electrical terminals of the transistor is a first one of the gate terminals.

24. The integrated circuit of claim 23 wherein:
the bias subcircuit is electrically coupled to a second one of the gate terminals of the transistor in a sense and feedback loop to bias the second one of the gate terminals of the transistor.

25. The integrated circuit of claim 19 wherein:
the first one of the electrical terminals of the transistor is a drain terminal of the transistor.

26. The integrated circuit of claim 19 wherein:
the active subcircuit comprises a multi-stage amplifier having multiple transistors;
the transistor is one of the multiple transistors; and
the transistor is in a first stage of the multi-stage amplifier.

27. The integrated circuit of claim 26 wherein:
a second stage of the multi-stage amplifier comprises an other transistor having electrical terminals; and
the bias subcircuit is electrically coupled to a first one of the electrical terminals of the other transistor in a sense and feedback loop to bias the first one of the electrical terminals of the other transistor.

28. The integrated circuit of claim 19 wherein:
the monocrystalline silicon substrate, the amorphous oxide material, the monocrystalline perovskite oxide material, and the monocrystalline compound semiconductor material form a composite substrate having a first side and a second side opposite the first side;
the active subcircuit is located at the second side of the composite substrate; and
the bias subcircuit is located at the first side of the composite substrate.

29. The integrated circuit of claim 28 further comprising:
flip chip bumps located adjacent to the second side of the composite substrate;
wire bonds located adjacent to the first side of the composite substrate; and
a support substrate electrically coupled to the flip chip bumps and the wire bonds,
wherein:
the composite substrate is mounted over the support substrate; and
the second side of the composite substrate faces towards the support substrate.

30. The integrated circuit of claim 19 wherein:
the monocrystalline silicon substrate, the amorphous oxide material, the monocrystalline perovskite oxide material, and the monocrystalline compound semiconductor material form a composite substrate having a first side and a second side opposite the first side;
the active subcircuit is located at the second side of the composite substrate; and
the bias subcircuit is located at the second side of the composite substrate.

31. A process for fabricating a semiconductor structure for integrated control of an active subcircuit comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a bias subcircuit at least partially in the monocrystalline silicon substrate;
forming the active subcircuit at least partially in the monocrystalline compound semiconductor layer; and
electrically coupling together the active subcircuit and the bias subcircuit.

32. The process of claim 31 wherein:
the monocrystalline silicon substrate, the amorphous oxide interface layer, the monocrystalline perovskite oxide film, and the monocrystalline compound semiconductor layer form a composite substrate having a first side and a second side opposite the first side;
forming the bias subcircuit further comprises:
forming the bias subcircuit adjacent to the first side of the composite substrate; and
forming the active subcircuit further comprises:
forming the active subcircuit adjacent to the second side of the composite substrate.

33. The process of claim 32 further comprising:
flip-chip bonding the active subcircuit to a support substrate; and
wire bonding the bias subcircuit to the support substrate.

34. The process of claim 31 wherein:
epitaxially forming the monocrystalline compound semiconductor layer further comprises:
selectively epitaxially forming the monocrystalline compound semiconductor layer over the monocrystalline silicon substrate;
the monocrystalline silicon substrate, the amorphous oxide interface layer, the monocrystalline perovskite oxide film, and the monocrystalline compound semiconductor layer form a composite substrate having a first side and a second side opposite the first side;
forming the bias subcircuit further comprises:
forming the bias subcircuit adjacent to the first side of the composite substrate; and
forming the active subcircuit further comprises:
forming the active subcircuit adjacent to the first side of the composite substrate.

35. The process of claim 34 further comprising:
etching a portion of the monocrystalline silicon substrate to form a recess in the monocrystalline silicon substrate,
wherein:
epitaxially forming the monocrystalline compound semiconductor layer further comprises:
selectively epitaxially forming the monocrystalline compound semiconductor layer in the recess of the monocrystalline silicon substrate.

36. The process of claim 31 further comprising:
sequentially etching portions of the monocrystalline compound semiconductor layer, the monocrystalline perovskite oxide film, and the amorphous oxide interface layer to expose a portion of the monocrystalline silicon substrate,
wherein:
the monocrystalline silicon substrate, the amorphous oxide interface layer, the monocrystalline perovskite oxide film, and the monocrystalline compound semiconductor layer form a composite substrate having a first side and a second side opposite the first side;
forming the bias subcircuit further comprises:
forming the bias subcircuit in the portion of the monocrystalline silicon substrate and adjacent to the first side of the composite substrate; and
forming the active subcircuit further comprises:
forming the active subcircuit adjacent to the first side of the composite substrate.

37. The process of claim 31 further comprising:
flip-chip bonding the active subcircuit and the bias subcircuit to a support substrate.

38. The process of claim 31 further comprising:
wire bonding the active subcircuit and the bias subcircuit to a support substrate.

39. The process of claim 31 wherein:
forming the bias subcircuit occurs before depositing the monocrystalline perovskite oxide film.
